(19) United States
(12) Patent Application Publication
(10) Pub. No.: US 2001/0052632 A1
(43) Pub. Date: Dec. 20, 2001

(54) SEMICONDUCTOR PACKAGE WITH AN ELECTRICAL STATIC DISCHARGE RESISTOR

(76) Inventors: TSUNG-CHIH WU, HSINCHU HSIEN (TW); TE-SHENG YANG, TAIPEI (TW)

Correspondence Address: DANIEL R MCCLURE, THOMAS KAYDEN HORSTEMEYER & RISLEY LLP, 100 GALLERIA PARKWAY N W STE 1500, ATLANTA, GA, 30339

(21) Appl. No.: 09/392,275

(22) Filed: Sep. 9, 1999

(51) Int. Cl. H01L 29/00

(52) U.S. Cl. 257/528

(57) ABSTRACT

A package with an electrical static discharge resistor. A chip is attached on a carrier with bumps and contacts. The carrier couples with the chip through the bumps. Electrical static discharge resistors between the bumps and the contacts are on the carrier.

### BACKGROUND OF THE INVENTION

1. Field of Invention

The present invention relates to an electrical static discharge (ESD) protective structure. More particularly, the present invention relates to a semiconductor package with an electrical static discharge resistor.

2. Description of Related Art

In the fabrication of an integrated circuit (IC) device, such as dynamic random access memory (DRAM) or statistic random access memory (SRAM), electrical static discharge effect is one of the main causal agents of integrated circuit device damage. For example, when one walks on a carpet with wafers, if relative humidity (RH) is high, an electrostatic voltage of about one hundred volts may exist on one's body and wafers. If the relative humidity is very low, the electrostatic voltage may be as high as about one thousand volts. When a conductive object contacts the wafers, the electrical static discharge effect may occur and damage the devices on the wafers. To avoid the electrical static discharge effect, an electrical static discharge circuit is formed in the device.

Furthermore, an electrical static discharge resistor is often designed to cooperate with the electrical static discharge circuit. The electrical static discharge resistor is formed in the current path between the electrical static discharge circuit and the contact of the semiconductor package to improve the electrical static discharge protection.

FIG. 1 is a schematic diagram of a conventional semiconductor package with an electrical static discharge resistor. Referring to FIG. 1, a circuit 14 formed in a chip 12 couples with a pin 20 of a semiconductor package 10 through an electrical static discharge circuit 16. An electrical static discharge resistor 18 is formed in a current path between the electrical static discharge circuit 16 and the pin 20.

Usually, the electrical static discharge resistor is formed within the chip, so that some problems are induced when the size of the chip is reduced. Since the electrical static discharge resistor is formed within the chip, the size of the electrical static discharge resistor should also be reduced when the chip is reduced. However, the reduction of the electrical static discharge resistor decreases the protective ability of the electrical static discharge circuit. If the size of the electrical static discharge resistor is not reduced, the size of the chip is still large and a layout problem occurs.

Additionally, the pin count of the semiconductor package is increased because the functions of the chip increases; thus, the number of the electrical static discharge resistors is also increased due to the increasing pin count of the semiconductor package. However, while operating the chip, a large amount of heat is generated by the large amount of the electrical static discharge resistors formed within the chip.

### SUMMARY OF THE INVENTION

The invention provides a semiconductor package with an improved electrical static discharge resistor. The electrical static discharge resistor keeps sufficient protective ability when the chip is reduced, and the size of the electrical static discharge resistor is not limited by the chip. The heat problem caused by the electrical static discharge resistors during chip operation is avoided.

As embodied and broadly described herein, the invention provides a semiconductor package with an electrical static discharge resistor. A chip is attached on a carrier with bumps and contacts. The carrier couples with the chip through the bumps. Electrical static discharge resistors between the bumps and the contacts are on the carrier.

In this invention, the electrical static discharge resistors are formed outside the chip, so that the size of the electrical static discharge resistor is not limited by the size of the chip. The protective ability of the electrical static discharge resistor is not affected. Additionally, heat generated by the electrical static discharge resistor during the chip operation is dissipated from the carrier and the semiconductor package.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram of a conventional semiconductor package with an electrical static discharge resistor;

FIG. 2 is a schematic diagram of a semiconductor package with an electrical static discharge resistor according to the invention;

FIG. 3 is a schematic diagram showing a bonding portion of a semiconductor package according to the invention in which a carrier is a leadframe;

FIG. 4 is a schematic diagram showing a bonding portion of another semiconductor package according to the invention in which a carrier is a leadframe; and

FIG. 5 is a schematic, cross-sectional diagram of a ball grid array package according to the invention.

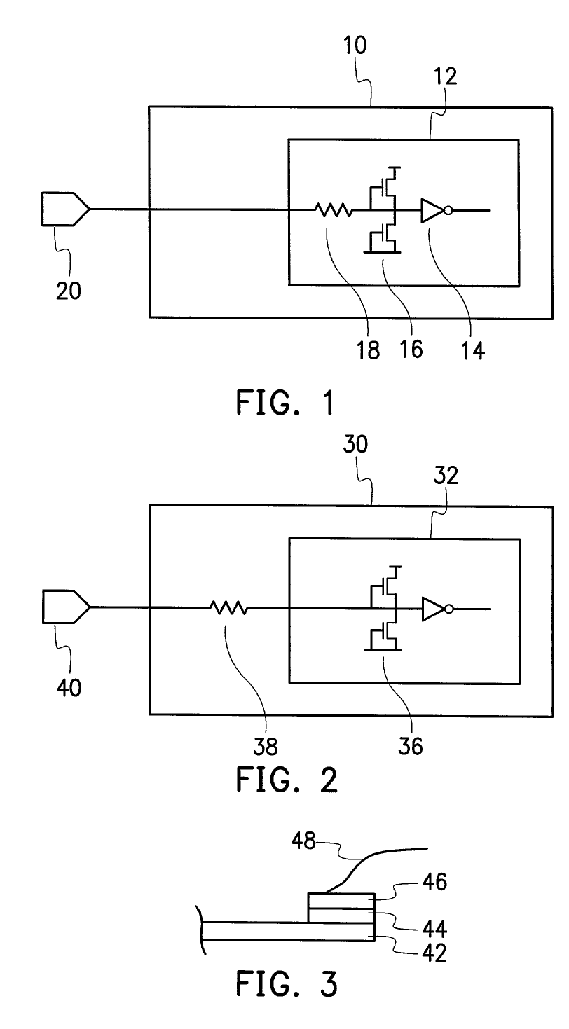

### DESCRIPTION OF THE PREFERRED EMBODIMENTS

In this invention, a semiconductor package with an electrical static discharge resistor is provided in which the size of the electrical static discharge resistor is not limited by the shrinkage of the chip, and the heat problem caused by the electrical static discharge resistor is avoided.

FIG. 2 is a schematic diagram of a semiconductor package with an electrical static discharge resistor according to the invention. Referring to FIG. 2, an electrical static discharge resistor 38 is similarly formed in a current path between an electrical static discharge circuit 36 within a chip 32 and a pin 40 of a semiconductor package 30. However, the electrical static discharge resistor 38 is formed outside the chip 32 in this invention. The electrical static discharge resistor 38 is formed on a carrier (not shown) of the semiconductor package 30. The carrier includes a leadframe or a substrate, for example, a ball grid array substrate.

The material used for the electrical static discharge resistor is preferably conductive paste whose resistance is adjusted. The resistance of the electrical static discharge resistor is adjusted to satisfy the design of the electrical static discharge circuit.

FIG. 3 is a schematic diagram showing a bonding portion of a semiconductor package according to the invention in which a carrier is a leadframe. Referring to FIG. 3, a bonding pad (not shown) on a chip (not shown) is coupled with a bump 46 such as silver paste on an inner lead 42 of a semiconductor package in which the carrier is a leadframe. An electrical static discharge resistor 44, for example, conductive paste whose resistance is adjustable is stacked between the bump 46 and the inner lead 42.

Since the electrical static discharge resistor 44 is formed on the inner lead 42, the size of the electrical static discharge resistor 44 is not affected by the shrinkage of the chip. When the chip is reduced, the size of the electrical static discharge resistor 44 need not be reduced. Moreover, the shape and the size of the electrical static discharge, resistor 44 can be varied in accordance with the design rule and is not limited by the chip. Additionally, heat generated by the electrical static discharge resistor 44 during the chip operation is dissipated from the inner lead 42 and the semiconductor package.

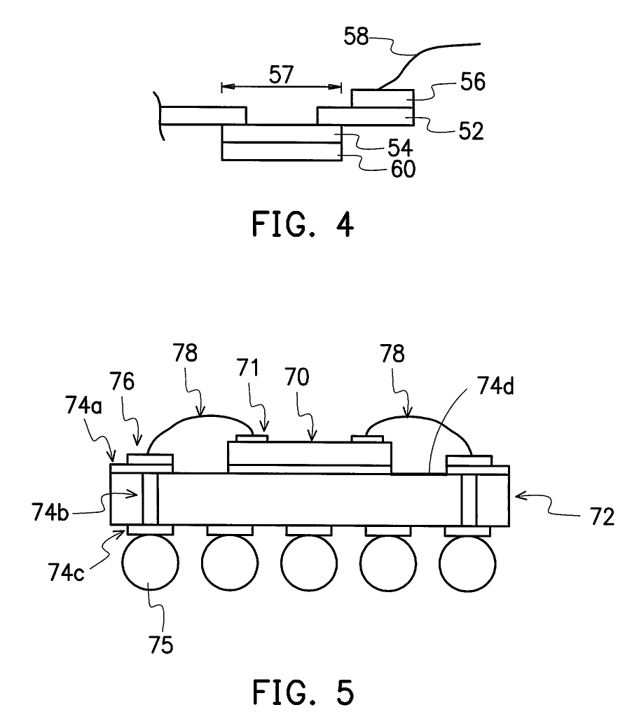

FIG. 4 is a schematic diagram showing a bonding portion of another semiconductor package according to the invention in which a carrier is a leadframe. Referring to FIG. 4, an electrical static discharge resistor 54 such as conductive paste whose resistance is adjustable is applied on a region 57 of an inner lead 52. Then, a supporter 60 is adhered on the electrical static discharge resistor 54. The supporter 60 protects the electrical static discharge resistor 54 and supports the inner lead 52 during the subsequent processes. A portion of the inner lead 52 located in the region 57 is removed by, for example, etching. A wire bonding process is performed; thus, a bonding pad (not shown) on a chip (not shown) is coupled with a bump 56 such as silver paste on the inner lead 52 through a wire 58.

In this embodiment, the electrical static discharge resistor is employed in the region of the inner lead. By removing the portion of the inner lead located in this region, the electrical static discharge resistor is the essential current path between the electrical static discharge circuit and the pin of the semiconductor package; thus, the electrical static discharge resistor achieves its protective function. Similarly, the shape and the size of the electrical static discharge resistor can be varied in accordance with the design rule and is not limited by the chip. Heat generated by the electrical static discharge resistant during the chip operation is dissipated from the inner lead and the semiconductor package.

The formations of the electrical static discharge in the above embodiments are different from each other. The concept of this invention is to form the electrical static discharge resistor outside the chip and to make the electrical static discharge resistor be the essential current path between the electrical static discharge circuit and the pin of the semiconductor package.

FIG. 5 is a schematic, cross-sectional diagram of a ball grid array package according to the invention. Referring to FIG. 5, a chip 70 is placed on a carrier 72. The material of the carrier 72 is, for example, BT resin, FR4 resin, ceramic or polyimide. A bonding pad 71 is coupled with a bump 76 on the carrier 72 through a wire 78 by, for example, wire bonding. An electrical static discharge resistor is formed in the current path between the electrical static discharge circuit (not shown) within the chip 70 and a solder ball 75 attached on the carrier 72. The electrical static discharge resistor may be formed between the carrier 72 and the bump 76 (as reference numeral 74a), in the carrier 72 (as reference numeral 74b), between the carrier 72 and the solder ball 75 (as reference numeral 74c) or on traces on the surfaces of the carrier 72 (as reference numeral 74d). Moreover, the electrical static discharge resistors 74a, 74b, 74c, 74d are formed simultaneously or some of the electrical static discharge resistors 74a, 74b, 74c, 74d may be formed to improve the protective ability.

In the aspect of the embodiments in which the carrier is a leadframe, the electrical static discharge resistor should be formed as the essential current path between the solder ball and the electrical static discharge circuit to achieve its protective ability. So, other positions on the substrate where the electrical static discharge resistor are formed in the path between the solder ball and the electrical static discharge circuit are suitable.

In the above embodiments, the carriers used are the leadframe and the substrate. However, the invention is not limited by the embodiments. The scope of this invention is to form the electrical static discharge resistor outside the chip, so this invention is also suitable for other kinds of package.

In this invention, the electrical static discharge resistors are formed outside the chip, so that the size of the electrical static discharge resistor is not limited by the size of the chip. The protective ability of the electrical static discharge resistor is not affected when the chip is reduced. Additionally, heat generated by the electrical static discharge resistor during the chip operation is dissipated from the carrier and the semiconductor package.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A semiconductor package with an electrical static discharge resistor, comprising:
a chip;
a carrier with a plurality of bumps and a plurality of pins, wherein the carrier adheres to a surface of the chip and couples with the chip through the bumps; and
a plurality of electrical static discharge resistors on the carrier.

2. The semiconductor package of claim 1, wherein the carrier includes a leadframe.

3. The semiconductor package of claim 1, wherein each of the electrical static discharge resistors is located between the carrier and one of the bumps.

4. The semiconductor package of claim 1, wherein each of the electrical static discharge resistors is located between the carrier and one of the pins.

5. The semiconductor package of claim 1, wherein the carrier includes a ball grid array substrate.

6. The semiconductor package of claim 5, wherein the ball grid array substrate has two surfaces, and a plurality of traces are formed on each surface.

7. The semiconductor package of claim 6, wherein the electrical static discharge resistors are located on the traces.

8. The semiconductor package of claim 5, wherein the electrical static discharge resistors are located in the ball grid array substrate.

9. A semiconductor package with an electrical static discharge resistor, comprising:
a chip;
a leadframe with a plurality of leads for holding the chip, wherein each lead has an inner lead portion, and each inner lead portion couples with the chip through a bump thereon;
a plurality of electrical static discharge resistors on the leadframe; and
a packaging material in which the chip and the inner lead portion are sealed.

10. The semiconductor package of claim 9, wherein each of the electrical static discharge resistors is located between the leadframe and one of the bumps.

11. The semiconductor package of claim 9, wherein each electrical static discharge resistor is located in a region of one lead, and a portion of each lead in the region is removed.

12. The semiconductor package of claim 11, wherein a supporter is located on each electrical static discharge resistor.

13. A semiconductor package with an electrical static discharge resistor, comprising:
a chip;
a substrate with a plurality of bumps and a plurality of contacts adhering to a surface of the chip, wherein the substrate couples with the chip through the bumps, and traces are formed on surfaces of the substrate; and
a plurality of electrical static discharge resistors on the substrate.

14. The semiconductor package of claim 13, wherein the substrate includes a BT substrate.

15. The semiconductor package of claim 13, wherein the substrate includes a FR4 substrate.

16. The semiconductor package of claim 13, wherein the substrate includes a ceramic substrate.

17. The semiconductor package of claim 13, wherein the substrate includes a polyimide substrate.

18. The semiconductor package of claim 13, wherein each of the electrical static discharge resistors is located between the substrate and one of the bumps.

19. The semiconductor package of claim 13, wherein each of the electrical static discharge resistors is located between the substrate and one of the contacts.

20. The semiconductor package of claim 13, wherein the electrical static discharge resistors are located on the traces.

21. The semiconductor package of claim 13, wherein the electrical static discharge resistors are located within the substrate.
